(19) United States
(12) Patent Application Publication
(10) Pub. No.: US 2003/0013299 A1
(43) Pub. Date: Jan. 16, 2003

(54) Method for forming a metal plug of a semiconductor device

(76) Inventors: Jung Geun Kim, Gyunggi-do (KR); Ki-Hong Yang, Gyunggi-do (KR)

Correspondence Address: MARSHALL, GERSTEIN & BORUN, 6300 SEARS TOWER, 233 SOUTH WACKER, CHICAGO, IL, 60606-6357, US

(21) Appl. No.: 10/185,413

(22) Filed: Jun. 28, 2002

(30) Foreign Application Priority Data
Jun. 29, 2001 (KR) 2001-38496

(51) Int. Cl. H01L 21/44

(52) U.S. Cl. 438/675; 438/686

(57) ABSTRACT

A method for forming a metal plug of a semiconductor device, in which the metal plug is formed by filling the contact hole through thermal treatment of the alloy layer formed by a physical vapor deposition method on the semiconductor device having the contact hole. Thus, a plug without a void can be formed even in a deep contact hole, the melting point and resistivity of the metallic material used in manufacturing the plug can be controlled and, accordingly, a semiconductor device having high integration can be provided.

### BACKGROUND OF THE DISCLOSURE

1. Field of the Disclosure

The disclosure relates to a method for forming a metal plug of a semiconductor device, in which the metal plug is formed by filling a contact hole through thermal treatment of the alloy layer formed by a physical vapor deposition (PVD) method on the semiconductor device having the contact hole, whereby a plug without a void can be formed even in a deep contact hole, and the melting point and resistivity of the metallic material used in manufacturing the plug can be controlled.

2. Description of Related Art

Generally, in manufacturing a semiconductor device, where the metal lines that function as the conductive lines are constructed in a plurality of layers, insulation layers are formed to insulate between these layers. As a photosensitive layer having a contact part is formed on the insulation layer and the insulation layer is then etched, a contact hole is formed on the insulation layer. Then, the contact hole is filled up with a metal layer to form a metal line.

The metal line is used as a bit line or a word line, and it connects the gate electrodes, capacitors, etc., vertically and horizontally to construct a semiconductor device.

FIG. 1 is a cross-sectional view showing the construction of a general metal plug of a semiconductor device. The depth of the contact hole is about 20000 Å, and the aspect ratio thereof is greater than 15. Accordingly, it is hard to fill the contact hole, and the contact hole can be filled only by chemical vapor deposition (CVD) providing superior filling characteristics. Furthermore, in order to secure stability at a high temperature, a metallic material with a very high melting point is required.

Tungsten and aluminum are generally used as the metallic material.

However, the tungsten requires WF₆ gas as a precursor when deposited by CVD, so a process for forming a barrier made of a metal such as TiN or Ti involves a preliminary step. Therefore, the number of steps increases, and it is very hard to fill the contact hole since the aspect ratio becomes worse.

Furthermore, the aluminum is deposited by CVD such as a hot aluminum process, however, there is a problem of outgassing of spin on glass (SOG) material that is generally an inter layer dielectric (ILD) material, since the contact hole is filled up at the temperature of about 450° C. Moreover, where an organic SOG material is used, contact bowing is generated during a cleaning process of the contact hole causing a void to form when the contact hole is filled.

### SUMMARY OF THE DISCLOSURE

It is an objective of the disclosure to provide a method for forming a metal plug of a semiconductor device, wherein the metal plug is formed by filling the contact hole through thermal treatment of the alloy layer formed by a PVD method on the semiconductor device having the contact hole, whereby a plug without a void can be formed even in a deep contact hole, and the melting point and the resistivity of the metallic material used in manufacturing the plug can be controlled.

To achieve this objective, the disclosure provides a method for forming a metal plug of a semiconductor device, including the steps of: depositing an insulation layer on a semiconductor substrate, forming a contact hole in the insulation layer; forming an alloy layer by depositing an alloy on the insulation layer; performing a thermal treatment to melt the alloy and fill the contact hole with the alloy; and removing a residue of the alloy from the insulation layer.

The alloy layer is formed by physical vapor deposition to secure the stability of the process, and the resistance of the alloy layer can be reduced or optimized by changing the composition ratio of the alloy layer.

### BRIEF DESCRIPTION OF THE DRAWINGS

Other objects and aspects of the disclosure will become apparent from the following description of an embodiment with reference to the accompanying drawings in which:

FIG. 1 is a cross-sectional view showing the construction of a general metal plug of a semiconductor device;

FIG. 2 is a graph showing the status of an alloy layer made of diatomic material, to illustrate the method for forming a metal plug of a semiconductor device according to the disclosure; and

FIGS. 3A to 3C are cross-sectional views showing the consecutive steps of a method for forming a metal plug of a semiconductor device according to the disclosure.

### DESCRIPTION OF THE PREFERRED EMBODIMENT

Hereinafter, the disclosure will be described in more detail with reference to the accompanying drawings.

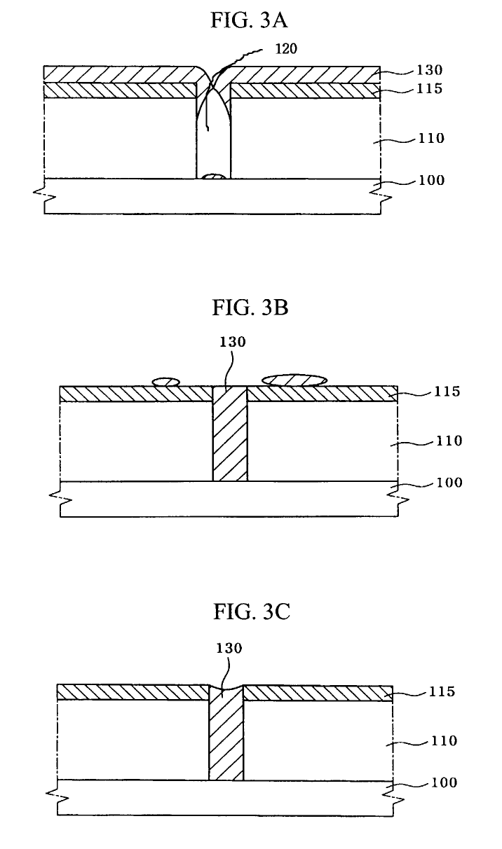

FIGS. 3A to 3C are cross-sectional views showing consecutive steps of a method for forming a metal plug of a semiconductor device according to the disclosure.

As shown in FIG. 3A, an insulation layer 110 and a non-wettable layer 115 of low interface energy are deposited consecutively on the semiconductor substrate 100 having a certain lower construction, and then a photosensitive layer (not shown) is formed thereon. A contact hole 120 is then formed by a contact etching process, and an alloy layer 130 is deposited by physical vapor deposition.

In that situation, an organic SOG material and an inorganic SOG material are used in forming the insulation layer 110. The non-wettable layer 115 with low interface energy facilitates the following process of removing a residue of the alloy.

The alloy is made of a plurality of metals having eutectic reaction at a temperature ranging from 400° C. to 700° C., and is formed by physical vapor deposition.

The plug is made of a metallic material with low resistivity, since it is preferable that the resistance of the plug is lower than that of the tungsten plug used in the prior art.

For example, the resistivity ρAB of an alloy of A and B is calculated as follows:

ρAB=ρA•XA+ρB•XB(XA:A%, XB:B%)

Here, XA+XB=100.

In the disclosed method, an alloy of two or more kinds of metals selected among W(10), Al(3), Ni(7.2), Ti(42.7), Au(2.4), Si(1000), Al(2.8), Cu(1.7) and Ag(1.6) is used, and the resistivity of the alloy can be calculated by the above equation.

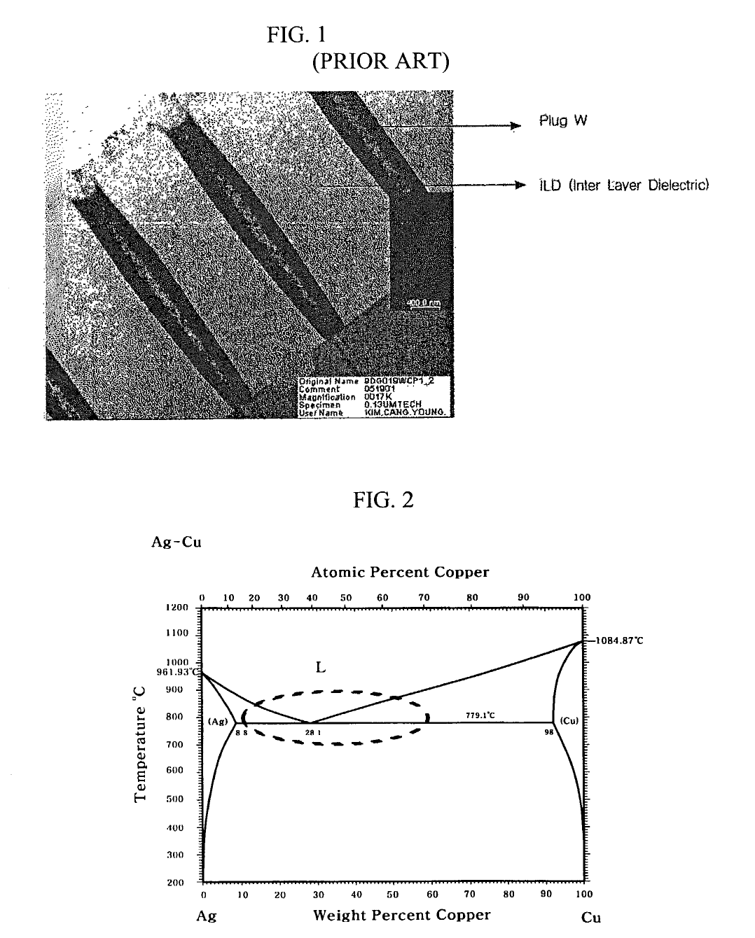

FIG. 2 is a graph showing the status of an alloy layer made of diatomic material, to illustrate the method for forming a metal plug of a semiconductor device according to the disclosure.

As shown in FIG. 2, the resistivity of the alloy of Ag-Cu having a combination ratio is 70:30 can be calculated as follows according to the above equation:

ρAg/Cu=ρAg•XAg+ρCu•XCu=(1.6×0.7)+(1.7×0.3)=1.63

Here, the unit of the resistivity of the metallic material is μΩ/cm.

In other words, it is preferable to use the metal of low resistivity such as Ag-Al, Ag-As, Ag-Cu, Ag-Si, Ag-Ti, Al-Au, Al-Cu, Au-Sb, Au-Si, Au-Ti, Mg-Ni and Mg-Sn. Further, the alloy of a diatomic material or a tri-atomic material can be used if the resistivity thereof is low and the eutectic reaction temperature thereof is in the range from 400° C. to 700° C.

Then, as shown in FIG. 3B, as the alloy layer 130 undergoes the thermal treatment, the alloy layer 130 flows into the contact hole 120 to fill up the contact hole 120. After that, the alloy layer 130 is solidified through cooling at room temperature.

Next, as shown in FIG. 3C, the residue of the alloy 130 is removed by a method such as scrubbing, etch back, and chemical mechanical planarization (CMP), etc.

According to the disclosed method for forming a metal plug of a semiconductor device, the metal plug is formed by filling the contact hole through the thermal treatment of the alloy layer formed by the PVD method on the semiconductor device having the contact hole, allowing a plug without a void to be formed even in the deep contact hole, the melting point and resistivity of the metallic material used in manufacturing the plug can be controlled, and the barrier metal process can be omitted.

Although a preferred embodiment of the method has been described, it will be understood by those skilled in the art that the method should not be limited to the described preferred embodiment, but that various changes and modifications can be made within the spirit and the scope of the disclosure. Accordingly, the scope of the disclosed method is not limited within the described range but the following claims.

What is claimed is:

1. A method for forming a metal plug of a semiconductor device, comprising the steps of:
depositing an insulation layer on a semiconductor substrate;
forming a contact hole in the insulation layer;
forming an alloy layer by depositing an alloy on the insulation layer;
performing a thermal treatment thereby melting the alloy layer and filling the contact hole with the alloy; and
removing a residue of the alloy from the insulation layer.

2. The method of claim 1, wherein the insulation layer is comprises at least one of an organic SOG material or an inorganic SOG material.

3. The method of claim 1, wherein the alloy comprises a diatomic metal or a tri-atomic metal having eutectic reaction at a temperature ranging from 400° C. to 700° C.

4. The method of claim 1, wherein the alloy is selected from the group consisting of Ag-Al, Ag-As, Ag-Cu, Ag-Si, Ag-Ti, Al-Au, Al-Cu, Au-Sb, Au-Si, AuTi, Mg-Ni, Mg-Sn, and mixtures thereof.

5. The method of claim 1, comprising controlling resistance of the plug and temperature for the thermal treatment by changing a composition ratio of the alloy.

6. The method of claim 1, comprising depositing the alloy by physical vapor deposition.

7. The method of claim 1, comprising, in the removing step, removing the residue of the alloy by at least one of scrubbing, etch back, and chemical mechanical planarization.

8. The method of claim 1, wherein the alloy comprises Ag-Cu combined at a ratio of 70:30.

9. The method of claim 1, further comprising a step of depositing a non-wettable layer on the insulation layer, before forming the contact hole.

10. The method of claim 1, further comprising, after filling the contact hole with the alloy, a step of cooling the contact hole, thereby solidifying the alloy.
